(19) United States
(12) Patent Application Publication
(10) Pub. No.: US 2006/0003542 A1
(43) Pub. Date: Jan. 5, 2006

(54) Method of oxidizing object to be processed and oxidation system

(76) Inventors: Keisuke Suzuki, Tokyo-To (JP); Kimiya Aoki, Tokyo-To (JP); Kota Umezawa, Tokyo-To (JP); Thomas Wilhelm Matthes, Dorfen (DE); Uwe Wellhausen, Dresden (DE); Norbert Dyroff, Bad Abbach (DE)

Correspondence Address: SMITH, GAMBRELL & RUSSELL, LLP, 1850 M STREET, N.W., SUITE 800, WASHINGTON, DC, 20036, US

(21) Appl. No.: 11/157,170

(22) Filed: Jun. 21, 2005

(30) Foreign Application Priority Data
Jun. 22, 2004 (JP) 2004-184201
May 13, 2005 (JP) 2005-141402

(51) Int. Cl. H01L 21/76

(52) U.S. Cl. 438/424

(57) ABSTRACT

A method of oxidizing an object to be processed comprises the steps of: providing an object to be processed W having a groove 4 formed on its surface in a processing vessel 22 capable of forming a vacuum therein, oxidizing the surface of the object to be processed in an atmosphere including active oxygen species and active hydroxyl species which are generated by supplying an oxidative gas and a reductive gas into the processing vessel to interact the gases. A temperature in the processing vessel during the oxidizing step is set to be equal to or less than 900° C. Thus, not only corner portions of shoulders of a trench (groove) but also corner portions of a bottom portion of the trench can be rounded to have curved surfaces so as to prevent a generation of facet.

### TECHNICAL FIELD

The present invention relates to a method of oxidizing a surface of a silicon or other substrate having a so-called groove (hereinafter also referred to as “trench”) formed thereon, an oxidation system, and a storage medium.

### BACKGROUND ART

Generally, when forming various elements such as transistors on a surface of a silicon substrate or a compound semiconductor substrate, a thick oxide film for isolation is formed to isolate elements between the transistors. A LOCOS process and a trench process are known for forming such an oxide film. In recent years, the trench process has been mainly employed because of a need for higher integration of elements. The trench method is carried out by etching a surface of a semiconductor substrate to form thereon a groove, i.e., a trench of a predetermined pattern, oxidizing the whole surface of the substrate including an inner surface of the trench to form a thin oxide film liner, and filling the trench with an insulator such as a silicon oxide film so as to electrically insulate the respective elements.

FIG. 5 is an enlarged sectional view showing a semiconductor substrate (wafer) on whose surface a thin oxide film liner is formed by oxidizing the whole surface of the wafer including an inner surface of a trench which is formed on the surface of the wafer. FIGS. 6A and 6B are enlarged views respectively showing portions A and B shown in FIG. 5. As shown in FIG. 5, an insulation film 2 such as a silicon nitride film is formed on a surface of an object to be processed W such as a silicon substrate. A groove, i.e., a trench 4 having a predetermined depth, is formed by etching the insulation film 2 and the surface of the object to be processed W. By oxidizing the surface of the object to be processed W having the trench 4 formed thereon, a thin oxide film liner of SiO₂, that is, an oxide film liner 6, is formed on the whole surface of the object to be processed W including the inner surface of the trench 4 and the surface of the insulation film 2.

By filling the respective trenches 4 with an insulator (not shown) of, e.g., SiO₂, a number of element-forming regions insulated from each other are formed. The purposes of forming the thin oxide film liner 6 are to restore defective parts on a silicon surface generated when the trench 4 is formed, to mitigate stresses of a filler on the trench 4, to improve filling characteristics of the filler, and so on. At the same time, corner portions 10 (see FIG. 6A) of shoulders 8 of the trench 4 and corner portions 14 (see FIG. 6B) of a bottom portion 12 of the trench 4 are rounded into curved surfaces, with a view to preventing a generation of electric field concentration which may cause a junction leakage.

The corner portions 10 and 14 are not easily rounded into curved surfaces. This is because plane directions in horizontal and vertical planes of each crystal on the surface of the substrate are different from each other, which creates different oxidation rates of the respective planes. Methods for forming the oxide film liner 6 to round the corner portions 10 and 14 include, for example, a dry-oxidation treatment carried out in an atmosphere where oxygen is present at a high temperature of about 1000° C., and an oxidation treatment carried out by adding HCl or DCE (dichlorethane). In addition, a process has been carried out in which the corner portions 10 and 14 of the trench 4 are exposed to a hydrogen atmosphere at a high temperature so as to round the corner portions 10 and 14 (see Japanese Patent Laid-Open Publication No. 2004-11747).

According to the above conventional methods, as shown in FIG. 6A, it is possible to surely round the corner portions 10 of the shoulders 8 of the trench 4 into curved surfaces. However, as shown in FIG. 6B, a crystal plane having a linear cross-section, that is, a facet 16, is generated on each of the corner portions 14 of the bottom portion 12 of the trench 4 at a boundary face between the oxide film liner 6 and a silicon material of the object to be processed W. The facet 16 may cause a crystal defect or the like, because stresses are concentrated on the facet 16 after the trench 4 is filled. In this case, a dry-oxidation treatment at a relatively lower temperature around 750° C. may be carried out to prevent a generation of the facet 16. However, although no facet is generated on the bottom portion 12 of the trench 4, new facets are generated on the shoulders 8 of the trench 4. Thus, such a method cannot be adopted.

### SUMMARY OF THE INVENTION

In view of the above disadvantages, the present invention is made to efficiently solve the same. An object of the present invention is to provide a method of oxidizing an object to be processed, an oxidation system, and a storage medium which can round not only corner portions of shoulders of a trench (groove) but also corner portions of a bottom portion of the trench into curved surfaces so as to prevent a generation of facets.

The present invention is a method of oxidizing an object to be processed comprising the steps of: providing an object to be processed having a groove formed on a surface thereof in a processing vessel capable of forming a vacuum therein; and oxidizing the surface of the object to be processed in an atmosphere including active oxygen species and active hydroxyl species which are generated by supplying an oxidative gas and a reductive gas into the processing vessel to make the gases interact with each other; wherein a temperature in the processing vessel during the oxidizing step is set to be equal to or less than 900° C.

According to the present invention, a surface of an object to be processed having a groove on its surface is oxidized in an atmosphere including active oxygen species and active hydroxyl species at a temperature of equal to or less than 900° C. Thus, not only corner portions of shoulders of a trench (groove) but also corner portions of a bottom portion of the trench can be rounded into curved surfaces so as to prevent a generation of facet.

In the method of oxidizing an object to be processed, a lower limit of the temperature in the processing vessel during the oxidizing step may be 400° C.

In the method of oxidizing an object to be processed, the temperature in the processing vessel during the oxidizing step may be in a range of from 750° C. to 850° C.

In the method of oxidizing an object to be processed, the oxidizing method comprises: a first oxidizing step for forming an oxide film having a thickness larger than a predetermined one by the oxidation treatment; and a second oxidizing step to be carried out after the first oxidizing step, for carrying out an oxidation treatment at a film-forming rate higher than that of the first oxidizing step.

In the method of oxidizing an object to be processed, the object to be processed may be a silicon substrate.

In the method of oxidizing an object to be processed, the processing vessel may have a predetermined length, and a plurality of objects to be processed may be provided in the processing vessel.

In the method of oxidizing an object to be processed, the oxidative gas may include one or more gases selected from the group consisting of O₂, N₂O, NO, NO₂, and O₃, and the reductive gas may include one or more gases selected from the group consisting of H₂, NH₃, CH₄, HCl, and deuterium.

The present invention is an oxidation system for oxidizing a surface of an object to be processed having a groove formed on a surface thereof comprising: a processing vessel capable of forming a vacuum therein; a holding means which holds a plurality of objects to be processed in the processing vessel; an oxidative gas supply means which supplies an oxidative gas to the processing vessel; a reductive gas supply means which supplies a reductive gas to the processing vessel; a heating means which heats the objects to be processed; and a system control means which controls the oxidation system to maintain the temperature in the processing vessel equal to or less than 900° C. while supplying the oxidative gas and the reductive gas to the processing vessel, so that a surface of each object to be processed is oxidized in an atmosphere including active oxygen species and active hydroxyl species generated by an interaction of the gases.

In the method of oxidizing an object to be processed, the processing vessel may have a vertical, cylindrical shape having an opened lower end, and the holding means holding the objects to be processed in a tier-like manner can be vertically loaded into the processing vessel and unloaded therefrom through the opened lower end of the processing vessel.

The present invention is a storage medium storing therein a program which controls an oxidation system by carrying out a method of oxidizing an object to be processed including the steps of: providing an object to be processed having a groove formed on a surface thereof in a processing vessel capable of forming a vacuum therein, and oxidizing the surface of the object to be processed in an atmosphere including active oxygen species and active hydroxyl species which are generated by supplying an oxidative gas and a reductive gas into the processing vessel to make the gases interact with each other, wherein a temperature in the processing vessel is maintained equal to or less than 900° C.

A method of oxidizing an object to be processed, an oxidation system, and a storage medium according to the present invention can provide the following excellent effect. That is, not only corner portions of shoulders of a trench (groove) but also corner portions of a bottom portion of the trench can be rounded into curved surfaces so as to prevent a generation of facets.

### BRIEF DESCRIPTION OF THE DRAWINGS

FIG. 1 is a structural view showing an example of an oxidation system for embodying a method of the present invention;

FIG. 2 is an enlarged cross-sectional view showing a semiconductor wafer on whose surface a thin oxide film liner is formed by oxidizing the whole surface of the wafer including an inner surface of a trench which is formed on the surface of the wafer;

FIGS. 3A to 3D are partially enlarged views showing temperature dependency of portions A and B shown in FIG. 2;

FIGS. 4A and 4B are illustrational views respectively showing a temperature change when carrying out an oxidation treatment including two steps;

FIG. 5 is an enlarged cross-sectional view showing a semiconductor substrate (wafer) in which a thin oxide film liner is formed on the surface by oxidizing the whole surface of the wafer including an inner surface of a trench which is formed on the surface of the wafer; and

FIGS. 6A and 6B are enlarged views respectively showing portions A and B shown in FIG. 5.

### DETAILED DESCRIPTION OF THE INVENTION

An embodiment of a method of oxidizing an object to be processed and an oxidation system according to the present invention is described in detail, with reference to the accompanying drawings.

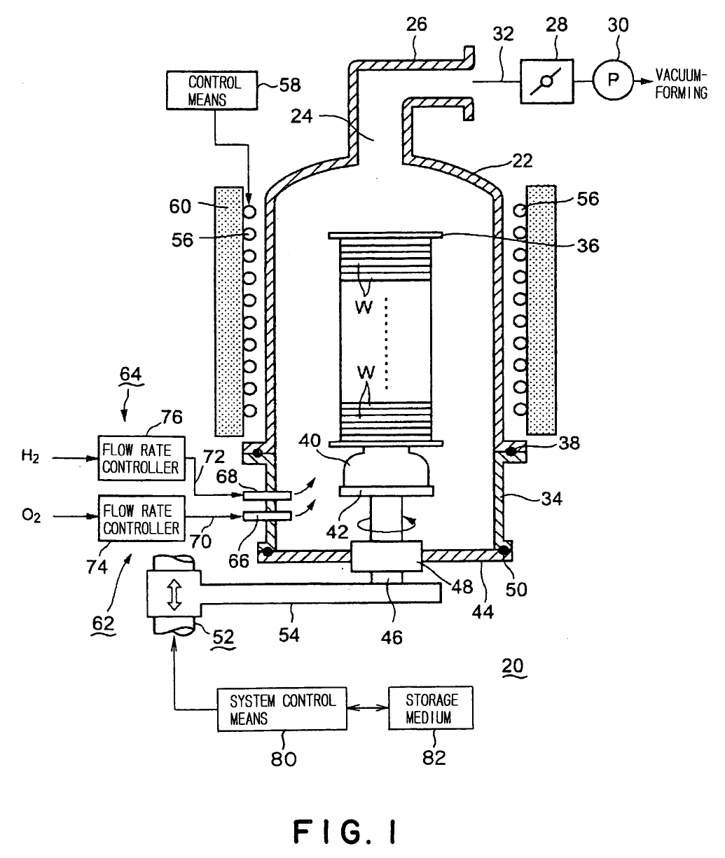

FIG. 1 is a structural view showing an example of an oxidation system for embodying the present invention. The oxidation system is described in the first place. As shown in FIG. 1, the oxidation system 20 includes a cylindrical processing vessel 22 of a vertical type which has a lower end opened, and has a predetermined length in a vertical direction. The processing vessel 22 may be made of, for example, quartz having a high heat resistance.

An opened exhaust port 24 is disposed on a top of the processing vessel 22. An exhaust line 26, which is bent at a right angle and transversely extends, for example, is connected to the exhaust port 24. A vacuum exhaust system 32, which has a pressure control valve 28 and a vacuum pump 30 disposed in series, is connected to the exhaust line 26. Thus, an atmosphere in the processing vessel 22 can be vacuumed and exhausted.

The lower end of the processing vessel 22 is supported by a tubular manifold 34 which is made of, for example, stainless steel. A wafer boat 36 made of quartz can be vertically taken in and out of a lower part of the manifold 34. The wafer boat 36 serves as a holding means, and contains a plurality of semiconductor wafers W such as silicon substrates as objects to be processed disposed thereon at predetermined pitches in a tier-like manner. A sealing member 38 such as an O-ring is provided between the lower end of the processing vessel 22 and the upper end of the manifold 34 so as to maintain an air-tightness of this part. In the present embodiment, the wafer boat 36 can hold about 50 pieces of wafers W having a diameter of 300 mm at substantially constant pitches in a tier like manner.

The wafer boat 36 is mounted on a table 42 through a heat insulation tube 40 made of quartz. The table 42 is supported on an upper end of a rotary shaft 46 passing through a cover 44 which opens and closes a lower opening of the manifold 34. A magnetic fluid seal 48 is disposed on a passing part of the rotary shaft 46 so as to air-tightly seal the rotary shaft 46 as well as rotatably support the same. A seal member 50 such as an O-ring is provided between a periphery of the cover 44 and the lower end of the manifold 34 so as to air-tightly seal the processing vessel 22.

The rotary shaft 46 is attached to an end of an arm 54 supported by an elevating mechanism 52 such as a boat elevator. Thus, the wafer boat 36 and the cover 44 can be vertically moved together. Alternatively, the table 42 may be secured to the cover 44 so that the wafers W are treated without rotating the wafer boat 36.

A heating means 56 as a heater, including carbon wire, which is described in, for example, Japanese Patent Laid-Open Publication No. 2003-209063 is disposed to surround the processing vessel 22. Thus, the processing vessel 22 inside the heating means 56 and the semiconductor wafers W contained in the processing vessel 22 can be heated. Such a carbon wire heater can provide a clean process, and has a satisfactory rising and lowering temperature property. A control means 58 such as a microcomputer is connected to the heating means 56, for controlling a temperature of the wafers W during an oxidizing step, which is described below. A heat insulation material 60 is disposed on an outer periphery of the heating means 56 so as to ensure a thermal stability of the heating means 56. Gas supply means for introducing and supplying various gases to the processing vessel 22 are disposed on the manifold 34.

Specifically, the manifold 34 has an oxidative gas supply means 62 for supplying an oxidative gas to the processing vessel 22, and a reductive gas supply means 64 for supplying the reductive gas to the processing vessel 22. The oxidative gas supply means 62 and the reductive gas supply means 64 respectively have an oxidative gas injection nozzle 66 and a reductive gas injection nozzle 68. Each nozzle 66 and 68 passes through a sidewall of the manifold 34, and an end thereof is inserted to a lower part as one of the opposite ends of the processing vessel 22. Flow rate controllers 74 and 76 such as mass flow controllers are respectively disposed on gas passages 70 and 72 which are extended from the respective injection nozzles 66 and 68. A system control means 80 such as a microcomputer controls the respective flow rate controllers 74 and 76 so that the gas flow rates thereof can be respectively controlled.

The system control means 80 controls the overall operation of the oxidation system 20. The control means 58 of the heating means 56 is under the control of the system control means 80. The system control means 80 includes a storage medium 82 such as a floppy disk or a flash memory which stores therein a program for controlling an operation of the oxidation system 20.

By way of example, O₂ gas is used as an oxidative gas, and H₂ gas is used as a reductive gas. Although not shown, an inert gas supply means for supplying inert gas such as N₂ gas according to need is disposed on the oxidation system 20.

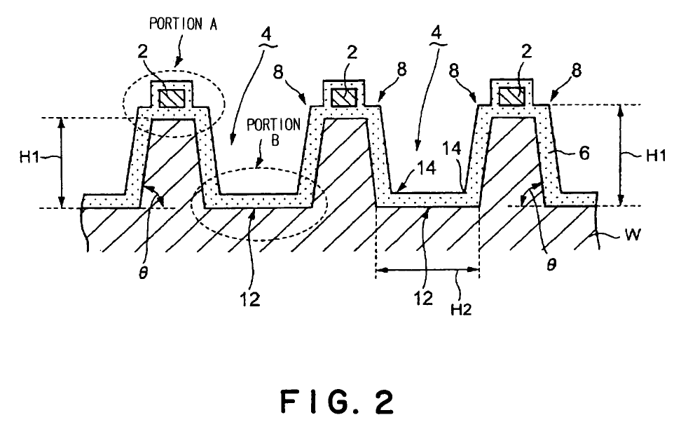

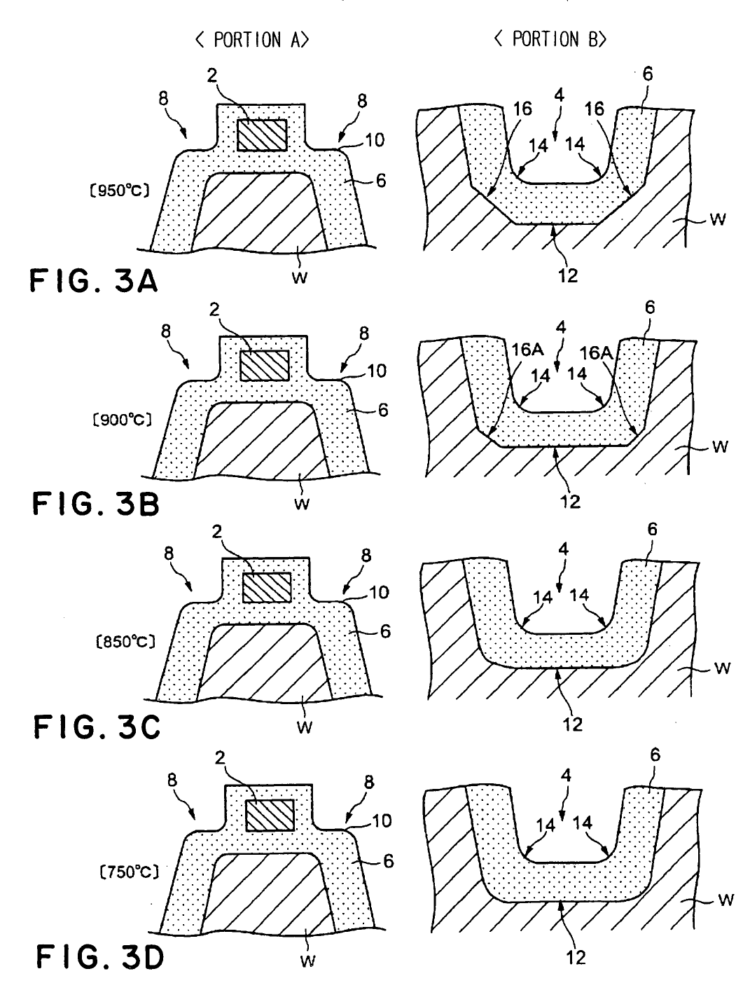

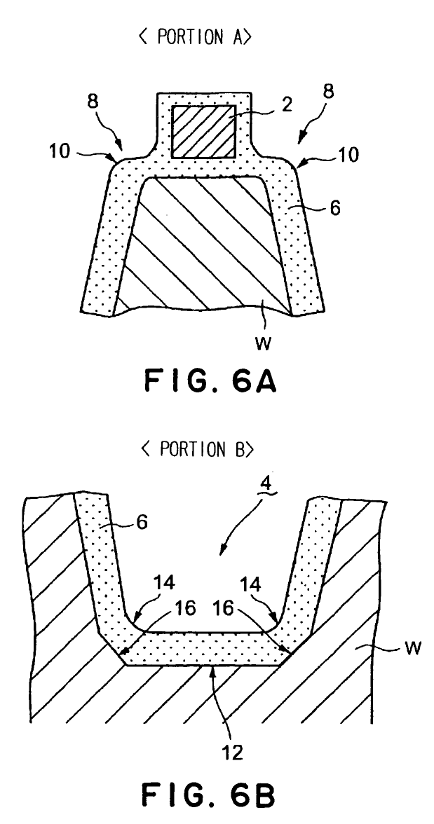

Then, an oxidizing method carried out by the oxidation system 20 as constituted above is described with reference to FIGS. 2 and 3. As mentioned above, the respective operations of the oxidation system 20 described below are controlled by the system control means 80 such as a computer. FIG. 2 is an enlarged cross-sectional view showing a semiconductor wafer on which a thin oxide film liner is formed by oxidizing the whole surface of the wafer including an inner surface of a trench which is formed on the surface of the wafer. FIGS. 3A to 3D are partially enlarged views showing temperature dependency of portions A and B shown in FIG. 2. In FIGS. 2 and 3A-3D, identical parts to those shown in FIGS. 5 and 6A-6B have the same reference numbers as those of FIGS. 5 and 6A-6B.

When the oxidation system 20 is in a waiting condition with the semiconductor wafers W such as silicon substrates being unloaded, the processing vessel 22 is maintained at a temperature lower than a process temperature. The wafer boat 36, which has a number of, e.g., 50 pieces of wafers W at a room temperature arranged thereon, is elevated to be loaded from below to the processing vessel 22 in a hot wall condition. The lower opening of the manifold 34 is closed by the cover 44 so that the processing vessel 22 is air-tightly sealed. As described above referring to FIG. 5, a trench (groove) of a predetermined pattern is formed on the surface of each semiconductor wafer W, by etching a wafer surface on which the insulation film 2 such as a silicon nitride film is formed (see, FIG. 2).

Then, the processing vessel 22 is vacuumed to maintain at a predetermined process pressure, and a supply power to the heating means 56 is increased. Thus, a wafer temperature is elevated to a process temperature for carrying out an oxidation treatment and then the temperature is stabilized. Thereafter, predetermined process gases required for carrying out the oxidation treatment, that is, O₂ gas and H₂ gas are supplied to the processing vessel 22 with their flow rates being controlled, through the oxidative gas injection nozzle 66 of the oxidative gas supply means 62, and the reductive gas injection nozzle 68 of the reductive gas supply means 64.

The O₂ gas and H₂ gas flow upward in the processing vessel 22 while interacting with each other in a vacuum atmosphere to generate active hydroxyl species and active oxygen species. The atmosphere including the active oxygen species and active hydroxyl species reaches the wafers W contained in the rotating wafer boat 36, so that surfaces of the wafers W are selectively subjected to the oxidation treatment. That is, an oxide film liner 6 of SiO₂ with a large thickness is formed on a silicon surface, while the oxide film of SiO₂ with a small thickness is formed on a surface of an insulation film of silicon nitride film. Then, the process gases or the gases generated by the interaction are discharged outside the system through the exhaust port 24 disposed on the top of the processing vessel 22.

The gas flow rate of the H₂ gas is, e.g., 300 sccm in a range of from 200 sccm to 5000 sccm. The gas flow rate of the O₂ gas is e.g., 2700 sccm in a range of from 50 sccm to 10000 sccm. Herein, an H₂ gas concentration is set to be e.g., about 10% relative to the all gas amount including oxygen.

Details of the oxidation treatment are described below. The O₂ gas and the H₂ which are individually introduced to the processing vessel 22 flow upward in the processing vessel 22 in a hot wall condition. An atmosphere mainly including active oxygen species (O*) and active hydroxyl species (OH*) is formed close to the wafers W through a combustion reaction of hydrogen. The surfaces of the wafers W are oxidized by these active species so that an SiO₂ film is formed on the wafers W. The process conditions are as follows: The wafer temperature is, e.g., 750° C. in a range of from 450° C. to 900° C. The pressure is, e.g., 133 Pa (1 Torr) in a range of from 13.3 Pa to 1330 Pa. The process time is e.g., 10 minutes to 120 minutes which is dependent on a desired film thickness to be formed. A desired film thickness is, for example, from about 60 Å to about 300 Å.

Forming processes of these active species are considered as described below. By individually introducing hydrogen and oxygen to the processing vessel 22 in a hot wall condition in a decompressed atmosphere, it is considered that the following combustion reaction processes of hydrogen occur close to the wafers W. In the below formulas, a chemical symbol with asterisk mark (*) indicates active species thereof.
H₂+O₂→H*+HO₂
O₂+H*→OH*+O*
H₂+O*→H*+OH*
H₂+OH*→H*+H₂O

When the H₂ gas and the O₂ gas are individually introduced to the processing vessel 22, 0* (active oxygen species), OH* (active hydroxyl species), and H₂O (steam) are generated in the course of the combustion reaction process of hydrogen whereby the wafer surfaces are oxidized to selectively form an SiO₂ film (oxide film liner 6), as described above. At this time, it is considered that the active species of O* and OH* largely affect the oxidation.

When carrying out the oxidation treatment as described above, the oxide film liner 6 can be rounded to have curved surfaces, not only on corner portions 10 of shoulders 8 of the trench 4 but also on corner portions 14 of the bottom portion 12 of the trench 4. Particularly, a facet 16 (see, FIG. 6B) as a crystal plane can be prevented from being generated at a boundary between the oxide film liner 6 and the silicon surface.

The reason why the generation of the facet can be prevented by oxidizing the wafers at a temperature of equal to or less than 900° C. is considered as follows: It is considered that a vector of a stress applied to crystals in a low temperature region is different from that in a high temperature region. That is, a stress applied to a bottom portion of a trench differs depending on a temperature, and no facet is generated at a low temperature.

When the wafer temperature (process temperature) during the oxidizing step is lower than 450° C., active oxygen species and active hydroxyl species are not sufficiently generated. This wafer temperature is disadvantageous because a facet as a crystal plane is generated on the corner portions 10 of the shoulders 8 of the trench 4, and because a film-forming rate is low. The wafer temperature higher than 900° C. during the oxidizing step is also disadvantageous because as described in the conventional oxidizing method, the facet 16 (see, FIG. 6B) larger than an allowable size is generated on the corner portions 14 of the bottom portion 12 of the trench 4.

To be specific, it is preferable that the wafer temperature is set to be in a range of from 750° C. to 850° C., in order to obtain a practically useful film-forming rate, and to securely prevent a generation of facet on the respective corner portions 10 and 14 of the respective shoulders 8 and the bottom portion 12 of the trench 4.

The process pressure of equal to or lower than 13.3 Pa is not practical because a film-forming rate is significantly lowered. On the other hand, the process pressure of equal to or higher than 1330 Pa results in an insufficient generation of active oxygen species and active hydroxyl species.

In FIG. 2, an aspect ratio (H1/H2) of the trench 4 is 4.5, with an inclination angle θ of a side surface of the trench 4 being equal to or more than 86.4°. As described above, it is needless to say that the trench 4 is filled with an insulation material such as SiO₂, in a subsequent step.

An oxidation treatment was carried out by changing process temperature (wafer temperature) to examine temperature dependency of the shapes of the oxide film liner on the respective corner portions. The evaluation results of the temperature dependency are described with reference to FIGS. 3A-3D.

The process conditions were as follows: The flow rates of the H₂ gas and O₂ gas were respectively 300 sccm and 2700 sccm. The process pressure was 46 Pa. The oxide film liners 6 of 100 Å in thickness were formed at the respective process temperatures of 950° C., 900° C., 850° C. and 750° C. The film-forming time were 20 minutes at the process temperature of 950° C., 30 minutes at 900° C., 50 minutes at 850° C., and 120 minutes at 750° C.

As shown in FIGS. 3A to 3D, regardless of the process temperatures, that is, in all the processes at the temperatures of 950° C., 900° C., 850° C., and 750° C., the shapes of the oxide film liners 6 on the corner portions 10 of the shoulders 8 of the trench 4 were respectively rounded to have curved surfaces without generation of any facet, which represented satisfactory results.

However, in the process at the process temperature of 950° C. (see, FIG. 3A), a clear facet 16 was observed on the corner portions 14 of the bottom portion 12 of the trench 4 at a boundary between the oxide film liner 6 and the silicon surface, which represented a disadvantageous result.

In the process at 900° C. (see FIG. 3B), only a very minute facet 16A which was practically useful, was observed on the corner portions 14 at a boundary between the oxide film liner 6 and the silicon surface, which represented a satisfactory result.

In the processes at 850° C. and 750° C. (see, FIGS. 3C and 3D), the shapes of the oxide film liners 6 on the corner portions 14 were respectively rounded to have curved surfaces without any facet at boundaries between the oxide film liners 6 and the silicon surfaces, which represented considerably satisfactory results.

Thus, it was confirmed that an upper limit of the process temperature for an oxide film is 900° C., and a preferable temperature is within a range of from 750° C. to 850° C.

In the above embodiment, the oxide film liner 6 was formed to have a desired film-thickness by carrying out a radical oxidation at a low temperature under the same process conditions. However, the present invention is not limited to this embodiment. It is possible that after forming an oxide film having a predetermined thickness, an oxidation treatment of a higher film-forming rate may be subsequently carried out to improve a throughput.

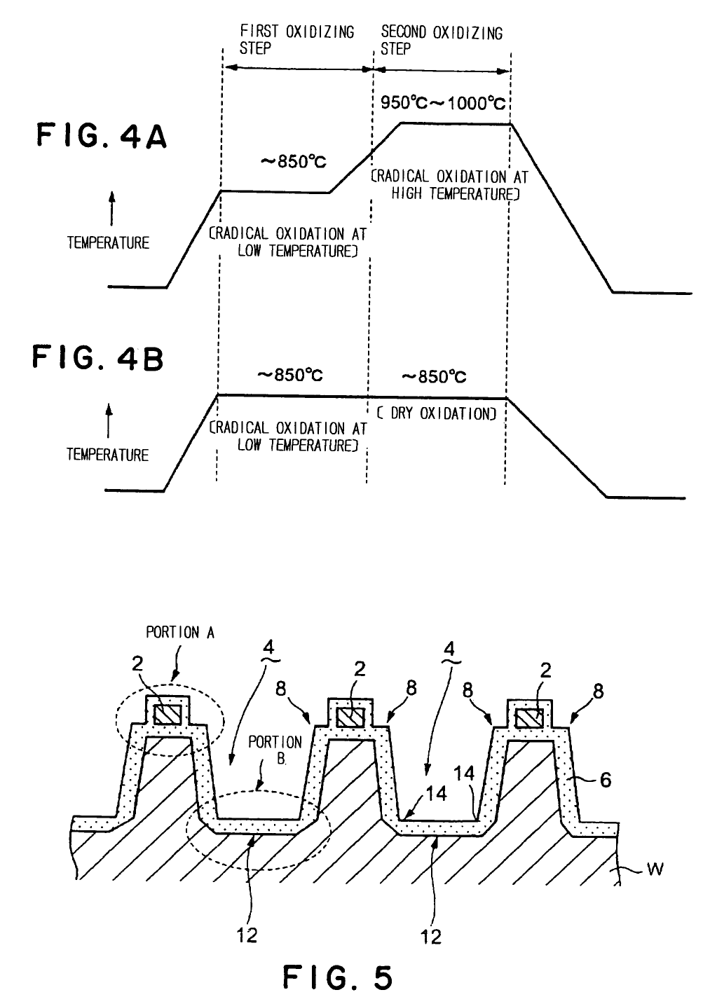

A film-thickness of the oxide film liner 6 may change according to a kind of devices, widely ranging from tens Å to hundreds Å. The above radical oxidation treatment at a lower temperature providing a lower film-forming rate is not practical for forming an oxide film having a desired film-thickness of hundreds Å. The film-forming rate thereof is too low to form such a thick oxide film. Thus, an oxidation treatment including two steps can be carried out to improve a throughput. FIGS. 4A and 4B are illustrational views respectively showing a temperature change when carrying out an oxidation treatment including two steps.

As shown in FIGS. 4A and 4B, the radical oxidation treatment at a lower temperature of a lower film-forming rate as described above is carried out in a first oxidizing step to form an oxide film having a predetermined film-thickness, and then an oxide treatment of a film-forming rate higher than that of the first oxidizing step is carried out in a second oxidizing step. That is, an oxide film without any facet on the bottom portion 12 of the trench 4 is formed in the first oxidizing step by a radical oxidation treatment at a lower temperature, and then the resulting oxide film liner 6 having a desired film-thickness is obtained in the second oxidizing step by subsequently carrying out an oxidation treatment of a higher film-forming rate.

In a process shown in FIG. 4A, the radical oxidation at a lower temperature as described above was carried out in the first oxidizing step at a temperature of less than 850° C., and subsequently the temperature was elevated to 950° C. to 1000° C. to carry out the radical oxidation at a higher temperature to provide a higher film-forming rate in the second oxidizing step.

In a process shown in FIG. 4B, the radical oxidation at a lower temperature as described above was carried out in the first oxidizing step at a temperature of less than 850° C., and subsequently, without changing the temperature but keeping the same, a dry oxidation was carried out by flowing, for example, only oxygen as gas species to provide a higher film-forming rate.

In the processes shown in FIGS. 4A and 4B, an oxide film having at least a thickness of 60 Å is formed in the first oxidizing step. As a result, when an oxidation treatment of a higher film-forming rate is carried out in the second oxidizing step, a generation of facet can be prevented because the oxide film which was thus formed in the previous radical oxidation at a lower temperature serves as a block film. In other words, when the film-thickness of the oxide film formed in the first oxidizing step is smaller than 60 Å, since such as oxide film does not have a sufficient block function, a facet may be generated in the oxide film formed in the second oxidizing step.

In the above embodiments the O₂ gas is used as the oxidative gas. However, not limited thereto, N₂O gas, NO gas, NO₂ gas, or the like may be used. In the above embodiments the H₂ gas is used as the reductive gas. However, not limited thereto, NH₃ gas, CH₄ gas or HCl gas may be used.

Not limited to the oxidation system for an oxidation treatment shown in FIG. 1, a processing vessel of a dual-tube type or an oxidation system of a single-wafer-fed type may be used. Needless to say, the present invention can be applied to semiconductor substrates of various sizes such as 6 inches, 8 inches, and 12 inches. Not limited to the semiconductor wafers as workpieces, the present invention may be applied to LCD substrates, glass substrates, and so on.

1. A method of oxidizing an object to be processed comprising the steps of:
providing an object to be processed having a groove formed on a surface thereof in a processing vessel capable of forming a vacuum therein; and
oxidizing the surface of the object to be processed in an atmosphere including active oxygen species and active hydroxyl species which are generated by supplying an oxidative gas and a reductive gas into the processing vessel to make the gases interact with each other; wherein
a temperature in the processing vessel during the oxidizing step is set to be equal to or less than 900° C.

2. The method of oxidizing an object to be processed according to claim 1, wherein
a lower limit of the temperature in the processing vessel during the oxidizing step is 400° C.

3. The method of oxidizing an object to be processed according to claim 1, wherein
the temperature in the processing vessel during the oxidizing step is in a range of from 750° C. to 850° C.

4. The method of oxidizing an object to be processed according to claim 1, wherein the oxidizing method comprises:
a first oxidizing step for forming an oxide film having a thickness larger than a predetermined one by the oxidation treatment; and
a second oxidizing step to be carried out after the first oxidizing step, for carrying out an oxidation treatment at a film-forming rate higher than that of the first oxidizing step.

5. The method of oxidizing an object to be processed according to claim 1, wherein
the object to be processed is a silicon substrate.

6. The method of oxidizing an object to be processed according to claim 1, wherein
the processing vessel has a predetermined length, and
a plurality of objects to be processed are provided in the processing vessel.

7. The method of oxidizing an object to be processed according to claim 1, wherein
the oxidative gas includes one or more gases selected from the group consisting of O₂, N₂O, NO, NO₂, and O₃, and
the reductive gas includes one or more gases selected from the group consisting of H₂, NH₃, CH₄, HCl, and deuterium.

8. An oxidation system for oxidizing a surface of an object to be processed having a groove formed on a surface thereof, comprising:
a processing vessel capable of forming a vacuum therein;
a holding means which holds a plurality of objects to be processed in the processing vessel;
an oxidative gas supply means which supplies an oxidative gas to the processing vessel;
a reductive gas supply means which supplies a reductive gas to the processing vessel;
a heating means which heats the objects to be processed; and
a system control means which controls the oxidation system to maintain the temperature in the processing vessel equal to or less than 900° C. while supplying the oxidative gas and the reductive gas to the processing vessel, so that a surface of each object to be processed is oxidized in an atmosphere including active oxygen species and active hydroxyl species generated by an interaction of the gases.

9. The oxidation system according to claim 8, wherein
the processing vessel has a vertical, cylindrical shape having an opened lower end, and
the holding means holding the objects to be processed in a tier-like manner can be vertically loaded into the processing vessel and unloaded therefrom through the opened lower end of the processing vessel.

10. A storage medium storing therein a program which controls an oxidation system by carrying out a method of oxidizing an object to be processed including the steps of: providing an object to be processed having a groove formed on a surface thereof in a processing vessel capable of forming a vacuum therein, and oxidizing the surface of the object to be processed in an atmosphere including active oxygen species and active hydroxyl species which are generated by supplying an oxidative gas and a reductive gas into the processing vessel to make the gases interact with each other, wherein a temperature in the processing vessel is maintained equal to or less than 900° C.
